(19) United States
(12) Patent Application Publication
(10) Pub. No.: US 2013/0071955 A1
(43) Pub. Date: Mar. 21, 2013

(54) PLASMA ETCHING METHOD

(71) Applicants: Hiroki Kintaka, Albany, OR (US); Toshihisa Ozu, Sendai (JP); Masahiko Takahashi, Beaverton, OR (US)

(72) Inventors: Hiroki Kintaka, Albany, OR (US); Toshihisa Ozu, Sendai (JP); Masahiko Takahashi, Beaverton, OR (US)

(73) Assignee: Tokyo Electron Limited, Tokyo (JP)

(21) Appl. No.: 13/234,449

(22) Filed: Sep. 16, 2011

(51) Int. Cl. H01L 21/66

(52) U.S. Cl. 438/9; 257/E21.528

(57) ABSTRACT

A method for processing a substrate to form a desired pattern by an etching process after forming a mask pattern over the substrate includes the steps of: forming two layers over the substrate; measuring a width of the mask pattern or an etched pattern of one of the two layers; and adjusting a flow rate of any one of HBr and other gases, used in the etching process, based on the measured width. The two layers may include a silicon nitride layer and an organic dielectric layer.

This application claims priority from U.S. provisional application Ser. No. 61/210,990, filed Mar. 24, 2009, U.S. provisional application Ser. No. 61/211,573, filed Mar. 31, 2009, and U.S. provisional application Ser. No. 61/211,614, filed Mar. 31, 2009, all three entitled “Plasma Etching Method”, the contents of which are incorporated herein by reference in their entirety.

### TECHNICAL FIELD

The present invention relates to semiconductor devices and their manufacturing methods. More specifically, it relates to etching plasma methods for providing high-resolution patterns with a desired critical dimension (CD) value.

### BACKGROUND OF THE INVENTION

In semiconductor manufacturing process, photolithography technology is used for forming resist patterns. In photolithography technology, a resist solution is first coated on a semiconductor or a liquid crystal display (LCD) substrate. Using a photo mask, the resist film is exposed to a pattern of intense light and then developed. As a result, a desired resist pattern is formed on the semiconductor or the LCD substrate. After forming the desired resist pattern, an etching process will take place for etching the semiconductor or the LCD substrate.

It is known that the processing results in each of the above-mentioned processing steps may not meet a target value, even though they are performed under constant processing conditions, due to existence of unwanted factors such as, for example, the condition of the substrate surface, atmospheric pressure, and fluctuations in temperature and relative humidity.

Conventionally, after processing a fixed number of substrates, a substrate is pulled out for inspection. During the inspection various parameters are measured and a decision is made as to whether the processing conditions are appropriate based on the inspection results. Example of those parameters may include a thickness of the resist film after the coating process, a line-width or critical dimension (CD) of the resist pattern after the developing process, accuracy in matching a base pattern with the resist pattern, inconsistencies on the developed surface, a defect on the development, and a line-width or critical dimension (CD) of the etched substrate and a defect on its surface after the etching process.

The processing conditions for each process steps may then be amended according to the decision made based on the inspection results. This operation amendment, which is very troublesome, may be performed by an experienced operator. To facilitate the amendment operation, a resist pattern forming process is proposed in Japanese Patent Application Publication No. 2002-190446. In this process a predetermined set of amendment parameters which are related to each specific measured parameter are first determined. The predetermined set of amendment parameters are then amended according at an automated inspection results.

For example, in the case where the line-width or the critical dimension (CD) of an etched substrate is considered as the specific measured parameter, the following amendment parameters may be amended to achieve the target value: 1) the light exposure intensity; 2) the heating time; 3) the developing time; 4) the etching time; and 5) the etching gas composition ratio. However, the above-mentioned publication does not specify how the gas composition ratio may affect the etching process for achieving the desired target value of critical dimension (CD).

Further, in Japanese Patent Application Publication No. 2003-209093 a substrate treatment process is disclosed in that a critical dimension (CD) of a resist pattern is precisely measured to form a desired circuit pattern after the etching step. In this process the critical dimension (CD) of the resist pattern is first measured. The measured result is then fed forwarded to an etching processing unit for adjusting the treatment conditions. By setting the optimal treatment conditions, a precise and desired circuit pattern can be obtained after the etching process. This technique provides a feed forward method for etching a desired pattern based on the measured resist film critical dimension (CD). However, similar to the previous publication, it fails to point out the specific conditions with regards to the etching gas types and their composition ratio for achieving the desired critical dimension (CD).

The present invention is proposed in view of the above aforementioned problems. The present invention provides a process for forming high-resolution patterns with a desired critical dimension (CD) using specific type of etching gas and their composition ratio.

### SUMMARY OF THE INVENTION

In accordance with one aspect of the present invention, there is provided a method for processing a substrate to form a desired pattern by an etching process after forming a mask pattern over the substrate. The method includes the steps of: forming two layers over the substrate, where the two layers include a silicon nitride layer and an organic dielectric layer; measuring a width of the mask pattern or an etched pattern of one of the two layers; and adjusting a flow rate of any one of HBr and other gases based on the measured width. The HBr and the other gases are being used in the etching process.

In accordance with a second aspect of the present invention, there is provided a method for processing a substrate to form a desired pattern by an etching process after forming a mask pattern over the substrate, the method includes the steps of forming three layers over the substrate, the three layers include a silicon nitride layer, an organic dielectric layer and a silicon-contained anti-reflective coating layer; measuring a width of the mask pattern or an etched pattern of one of the three layers; and adjusting a flow rate of any one of CF₄ and CHF₃ based on the measured width. The CF₄ and CHF₃ are being used in the etching process.

### BRIEF DESCRIPTION OF THE DRAWINGS

FIG. 1 illustrates schematically an embodiment of a target structure before and after performing a plasma etching process.

FIG. 2 illustrates schematically an alternative embodiment of a target structure and a cross-sectional view of an experimental sample after patterning the silicon nitride (SiN) layer.

FIG. 3 depicts a schematic diagram of an embodiment of a plasma processing device.

FIG. 4 depicts a schematic diagram of an embodiment of a line-width measurement device integrated into a coater developer.

FIG. 5 depicts a schematic diagram of an alternative embodiment of a line-width measurement device integrated into an etching device.

FIG. 6 illustrates an embodiment of a process for adjusting a line-width of patterns where multiple layers are etched.

FIG. 7 depicts a schematic diagram of an alternative embodiment of a stand-alone line-width measurement device.

FIG. 8 illustrates cross-sectional views of experimental samples showing a dense pattern and an isolated pattern after performing a plasma etching process at each specific layer.

FIG. 9 illustrates cross-sectional views of experimental samples and their critical dimension (CD) as a function of over etching (OE) time treatment.

FIG. 10 illustrates cross-sectional views of experimental samples and their critical dimension (CD) as a function of HBr flow rate.

FIG. 11 illustrates cross-sectional views of experimental samples showing a dense pattern and an isolated pattern for various etching gas type.

FIG. 12 illustrates cross-sectional views of experimental samples and their critical dimension (CD) as a function of Ar/HBr/O2 series flow rate.

FIG. 13 illustrates cross-sectional views of experimental samples and their critical dimension (CD).

FIG. 14 illustrates microwave power, RF power, and RF voltage of each mask layer as a function of time.

FIG. 15 illustrates cross-sectional views of experimental samples and their critical dimension (CD).

FIG. 16 illustrates cross-sectional views of experimental samples and their critical dimension (CD).

### DETAILED DESCRIPTION OF INVENTION

Embodiments of the present invention will be described hereinafter with reference to the accompanying drawings, in which preferred exemplary embodiments of the invention are shown. The ensuing description is not intended to limit the scope, applicability or configuration of the disclosure. Rather, the ensuing description of the preferred exemplary embodiments will provide those skilled in the art with an enabling description for implementing preferred exemplary embodiments of the disclosure. It should be noted that this invention may be embodied in different forms without departing from the spirit and scope of the invention as set forth in the appended claims.

This disclosure relates in general to semiconductor devices and their manufacturing process. More specifically, it relates to etching plasma methods for providing high-resolution patterns with a desired critical dimension (CD) value.

Embodiments of the present invention are directed to an etching process for controlling the line-width or the critical dimension (CD) of a silicon (Si) pattern. The silicon (Si) pattern is formed using a silicon nitride (SiN) hard-mask pattern. The silicon nitride (SiN) hard-mask pattern is, in turn, formed using a tri-layer mask pattern. The tri-layer mask pattern includes an organic dielectric layer (ODL). In order to obtain the desired silicon (Si) pattern with a predetermined critical dimension (CD) value, the line-width or the critical dimension (CD) of the silicon nitride (SiN) hard-mask pattern, formed on a silicon (Si) substrate, should be precisely controlled. This is achieved by adding hydrogen bromide (HBr) in a mixed atmosphere of nitrogen and oxygen (N₂/O₂) while patterning the organic dielectric layer (ODL).

By adding hydrogen bromide (HBr) and increasing its flow rate, hydrogen (H) concentration is reduced on the surface of the ODL layer due to the extraction of oxygen (O). As a result, an organic dielectric layer (ODL) with high carbon content is created. The high carbon content of the ODL layer generates carbon-carbon bonds which makes the organic dielectric layer (ODL) more rigid. The rigid property of ODL layer provides a better controllability for obtaining a predetermined value of critical dimension (CD) by reducing horizontal etching rate especially when the CD value is thinner than the target value.

Moreover, the high carbon content of the ODL layer generates a plurality of bromide-carbon bonds on the surface of the ODL pattern. As a result, a thin layer of carbon bromide (CBrx) is deposited over the ODL pattern as a side wall protection. This leads to thicken the ODL's critical dimension (CD).

According to one embodiment of the present invention, a desired critical dimension (CD) value is carried out by adjusting the hydrogen bromide (HBr) flow rate while performing a main etching (ME) step over the organic dielectric layer (ODL). By increasing the hydrogen bromide (HBr) flow rate, the critical dimension (CD) of ODL pattern tends to increase in value.

According to another embodiment, the critical dimension (CD) of ODL pattern may also be adjusted by performing an over etching (OE) step after completing the main etching (ME) step. In the over etching (OE) step, the desired critical dimension (CD) value may be carried out by adjusting the nitrogen to oxygen ratio (N₂/O₂) and adding appropriate amount of hydrogen bromide (HBr). Accordingly, if the difference between actual CD value and targeted value is relatively greater, adjustment can be done for main etching (ME) process, and when the difference is relatively smaller adjustment can be done for over etching (OE) process.

In one embodiment, the critical dimension (CD) value may increase by setting the hydrogen bromide (HBr) flow rate to a fix value while extending the over etching time period. In an alternative embodiment, the critical dimension (CD) value may be thickened by increasing the hydrogen bromide (HBr) flow rate. This leads to a higher composition ratio of hydrogen bromide (HBr) gas to other gases in the overall atmosphere.

According to yet another embodiment, the desired critical dimension (CD) value may be carried out in the ODL over etching (OE) step by adjusting the nitrogen to oxygen ratio (N₂/O₂) and adding chlorine (Cl₂) gas.

According to yet another embodiment, the desired critical dimension (CD) value may be carried out by adding hydrogen bromide (HBr) in a mixed atmosphere of argon and oxygen (Ar/O₂), instead of nitrogen and oxygen (N₂/O₂), while patterning an organic dielectric layer (ODL). In this embodiment, the critical dimension (CD) of ODL layer may increase by reducing the oxygen (O₂) flow rate.

According to an alternative embodiment of the present invention, a desired pattern with a predetermined critical dimension (CD) value may be achieved while patterning a silicon-contained anti reflective coating (Si-ARC) layer. In this embodiment, the line-width or the critical dimension of the Si-ARC layer may increase or decrease by adjusting a ratio of tetrafluoromethane to trifluoromethane (CF₄/CHF₃) gas.

According to yet another embodiment, a desired pattern with a predetermined critical dimension (CD) value may be carried out by adjusting a level of an RF bias power source. In this embodiment, the critical dimension (CD) value is proportional to the applied RF bias level (power). This means the higher the RF bias level is, the thicker is the critical dimension (CD) value. Conversely, a lower RF bias level provides a thinner critical dimension (CD) value.

The parameters to be adjusted in the above-mentioned embodiments, such as, for example, the hydrogen bromide (HBr) flow rate in the ODL patterning step, the (CF₄/CHF₃) ratio in the Si-ARC patterning step, and the RF bias level, are determined based on measuring the critical dimension (CD) of a resist pattern or any mask pattern.

According to one embodiment, the measured value of the resist pattern in a semiconductor substrate after developing process is used to determine the appropriate setting conditions for performing the following etching step of layers such as, for example, the organic dielectric layer (ODL) or the silicon-contained anti reflective coating (Si-ARC) layer in the same semiconductor substrate.

According to another embodiment, the measured value of the resist pattern or the etched pattern of the organic dielectric layer (ODL) or the silicon-contained anti reflective coating (Si-ARC) layer in one semiconductor substrate are used to determine the appropriate setting conditions for performing the etching step in another semiconductor substrate.

According to yet another embodiment, the measured value of the etched pattern of the organic dielectric layer (ODL) or the silicon-contained anti reflective coating (Si-ARC) layer in a semiconductor substrate are used to determine the appropriate setting conditions while performing the etching step in the same semiconductor substrate.

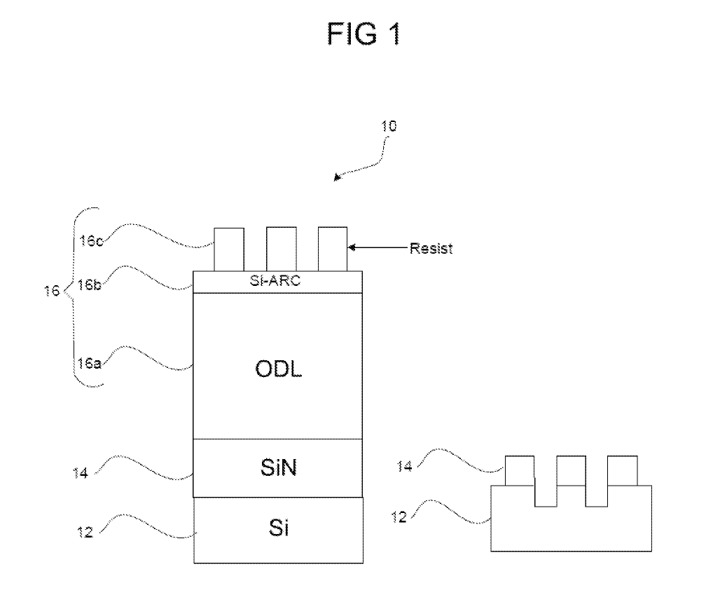

Referring first to FIG. 1, an embodiment of a target structure 10 before and after performing a plasma etching process is shown. As shown in this figure, the target structure 10 may include a silicon (Si) substrate 12, a hard mask silicon nitride (SiN) layer 14, and a tri-layer structure 16. The tri-layer structure 16 includes an organic dielectric layer (ODL) 16a, a silicon-contained anti reflective coating (Si-ARC) layer 16b, and a resist pattern 16c. To control precisely a final silicon (Si) pattern, a hard-mask pattern of the SiN layer 14 should be formed accurately on the Si substrate 12. In order to realize desired shape (CD value or line-width included) of the hard-mask pattern of the SiN layer 14, the hard-mask pattern of the SiN layer 14 can be etched using the tri-layer structure 16 (16a, 16b and 16c). More specifically, after forming the desired resist pattern 16c, subsequent etching processes will be performed, respectively, for the Si-ARC layer 16b, the ODL layer 16a, and the hard mask silicon nitride (SiN) layer 14, to finally transfer the whole pattern into the silicon (Si) substrate 12 by etching the Si substrate 12 through the pattern of SiN layer 14 as a hard mask. The final silicon (Si) substrate pattern 12 with some remaining residual SiN pattern 14 is also shown in FIG. 1.

As described previously, the line-width or critical dimension (CD) of the resist pattern 16c may not meet a desired target value, due to existence of unwanted factors such as, for example, the condition of the substrate surface, atmospheric pressure, and fluctuations in temperature and relative humidity. Therefore, the subsequent etching processes may not provide the desired target pattern of Si-ARC, ODL, SiN and the silicon (Si) substrate 12. To evaluate the above-mentioned point, an experimental sample is first manufactured, based on an alternative target structure. The experimental sample is then subjected to a conventional plasma etching process. In the following, the alternative target structure with its desired target pattern, after performing the plasma etching process, is described in detail.

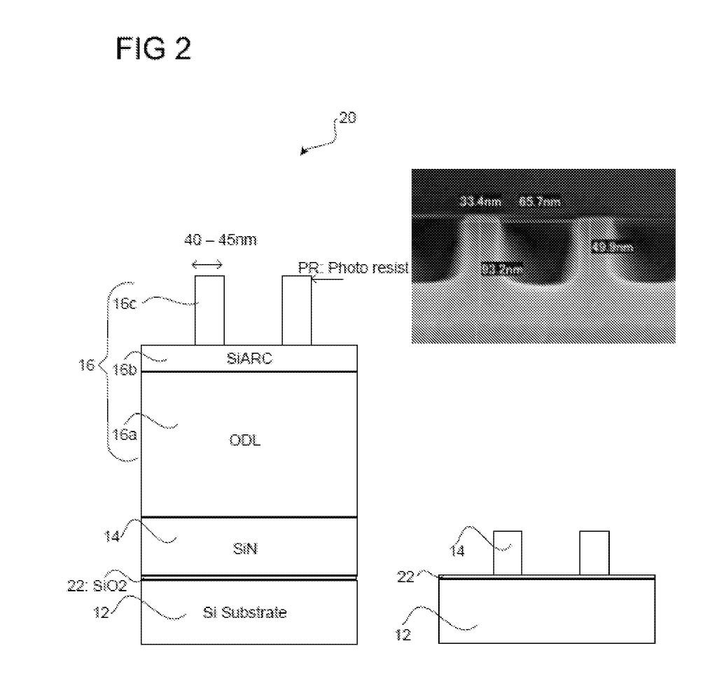

Referring next to FIG. 2, an alternative embodiment of a target structure 20 used for performing a plasma etching process is shown. The target structure 20 is different from the target structure 10 in that an additional silicon dioxide (SiO₂) layer 22 is interposed between the silicon substrate layer 12 and the hard mask silicon nitride (SiN) layer 14. Similar to the target structure 10, a tri-layer structure 16 is formed over the hard mask silicon nitride (SiN) layer 14. In this embodiment, the desired critical dimension (CD) for the resist pattern 16c is set to be about 40-45 nm. It will be appreciated that such a specific example is shown for illustrative purposes and is not intended to be limiting. The desired target pattern, after performing the plasma etching process, is also shown schematically in FIG. 2.

A cross-sectional view of the experimental sample after patterning the silicon nitride (SiN) layer 14 is shown in FIG. 2. As shown in this figure, the critical dimension (CD) of the silicon nitride pattern is about 33.4 nm, which is about 7 nm thinner compared to the desired critical dimension (40-45 nm). The measured distance between patterns is about 65.7 nm while the measured pattern height is about 49.9 nm.

In the conventional plasma etching process, most mask material is etched somewhat isotropically. That means the etching proceeds somewhat horizontally as well. Therefore, when the plasma etching process is applied to layer such as, for example, the organic dielectric layer (ODL) 16a, a side etching occurs simultaneously with a vertical etching of the ODL 16a. As a result, a cross-sectional shape of the mask pattern of the ODL 16a becomes far from a desired rectangular shape, instead becomes a tapered skirt shape, for example. Then, the SiN layer 14 etched through the ODL mask will not become a target shape as designed. Ideally, a directional etching with no etching in the horizontal direction is preferred. However, in practice, anisotropic etching with a smaller etching rate in horizontal direction is desirable.

As a countermeasure against the lateral etching of the ODL layer 16a and also to control the critical dimension (CD) of the pattern of the SiN layer 14, the present invention provides a plasma over etching (OE) process in which certain amount of hydrogen bromide (HBr) is added into the mixed atmosphere of nitrogen and oxygen (N₂/O₂) while patterning the organic dielectric layer (ODL) 16a. Various processing conditions with regards to the addition of hydrogen bromide (HBr) gas are investigated. These investigations are mainly performed to ascertain the ODL side wall protection mechanism and also to establish a process for controlling critical dimension (CD) while etching. Example of those processing conditions may include the HBr flow rate, the etching time, the etching gas type, bias power applied to the substrate and their composition ratio.

On the other hand, several control methods may be used, during the plasma etching process of the present invention, to provide a high-resolution (accurate) pattern with a predetermined critical dimension (CD) on the silicon (Si) substrate 12. Example of those control methods may include a feed-forward control process, a feed-back control process, and a dynamic (in-situ) control process. In the following, each of the above-mentioned control processes will be explained individually in detail.

In one embodiment, a feed-forward process control is used for obtaining a pattern with a predetermined critical dimension (CD). In this embodiment, the line-width or the critical dimension (CD) of the resist pattern 16c is first measured using any commercialized device. An integrated metrology (IM) device with optical measurement, e.g., scatterometory can be adopted. As will be described further below, in some embodiments, the line-width (CD) measurement device is integrated into a coater developer where latent or developed CD value of the photo resist after exposure is measured before the substrate is transferred to an etching device for subsequent etching process. In other embodiments, the CD measurement can be carried out in an IM device combined with the etching device where CD measurement is carried out right before the start of actual etching process. In alternative embodiments, the CD measurement may be conducted by a standalone measurement system instead of IM tool. The detail description of the line-width or CD measurement device will be described further below. After measuring the line-width or the critical dimension (CD) of the resist pattern 16c, a determination is made as to whether the critical dimension (CD) of the resist pattern 16c meets its desired target value. In the case where the critical dimension (CD) of the resist pattern 16c does not meet its desired target value, appropriate setting conditions with regards to a flow rate and type of plasma etching gas are first determined. The setting conditions are then adjusted, in the same semiconductor substrate, for the subsequent etching process of the Si-ARC layer 16b or the ODL layer 16a.

In an alternative embodiment, a feed-back process control is used for obtaining a pattern with a predetermined critical dimension (CD). In this alternative embodiment, the line-width or the critical dimension (CD) of the Si-ARC pattern 16b or the ODL layer 16a is first examined. A determination is made as to whether the critical dimension (CD) of the ODL pattern 16a (Si-ARC pattern 16b) meets its desired target value. In the case where the critical dimension (CD) of the ODL pattern 16a (Si-ARC pattern 16b) does not meet its desired target value, appropriate setting conditions with regards to a flow rate and type of plasma etching gas are determined. The setting conditions are sent to the etching device then adjusted for another semiconductor substrate to provide a predetermined critical dimension (CD) of mask patterns such as the SiN hard mask pattern 14, the ODL pattern 16a, the Si-ARC pattern 16b and the resist pattern 16c, on the silicon (Si) substrate 12.

In yet another alternative embodiment, a dynamic process control (in-situ) can be used for obtaining a pattern with a predetermined critical dimension (CD). In this embodiment, the line-width or the critical dimension (CD) of the ODL pattern 16a or the SiN hard mask pattern 14 is first measured during the etching process and the appropriate setting conditions with regard to a flow rate and type of plasma etching gas are adjusted dynamically during the plasma etching process of the ODL layer 16a or the SiN layer 14. In the following, an etching device and a line-width or CD measurement device will be explained individually in detail.

Etching Device:

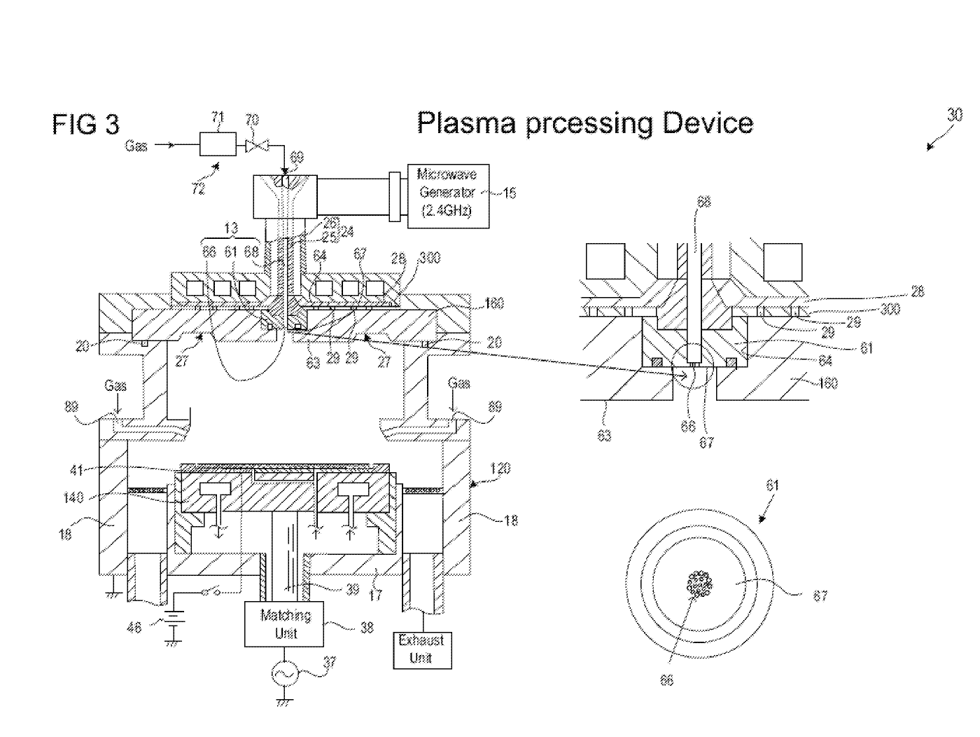

FIG. 3 illustrates a schematic diagram of an embodiment of a plasma processing device 30. As shown in this figure, the plasma processing device 30 includes a process vessel 120, a radial line slot plate 300, a substrate holder 140, and a dielectric window 160. The process vessel 120 may include a bottom portion 17, located beneath substrate holder 140 and cylindrical sidewall 18, which extend upwardly from the circumference of the bottom portion 17. An upper side of the process vessel 120 is open-ended. The dielectric window 160 is placed opposite to the substrate holder 140 and is sealed to the upper side of the process vessel 120 via O rings 20. The plasma processing device 30 further includes a controller, not shown in this figure, to control the processing conditions and overall operation of the device 30.

An external microwave generator 15 provides a microwave power of a predetermined frequency, e.g., 2.45 GHz, to the radial line slot plate 300 via a coaxial waveguide 24 and a slow-wave plate 28. The coaxial waveguide 24 may include a central conductor 25 and a circumferential conductor 26. The microwave power is then transmitted to the dielectric window 160 through a plurality of slots 29 provided on the radial line slot plate 300. The microwave from the microwave generator 15 generates an electric field just below the dielectric window 160, which in turn causes excitation of a plasma gas, e.g., nitrogen (N₂) gas or argon (Ar) gas, within the process vessel 120. A concave part 27, provided on an inner side of the dielectric window 160, enables an effective plasma generation inside the process vessel 120.

An external high-frequency power supply source 37 is electrically connected to the substrate holder 140 via a matching unit 38 and an electric power supply pole 39. The high-frequency power supply source 37 generates an RF bias power of a predetermined frequency, e.g., 13.56 MHz, for controlling ions energy that are drawn to a substrate. The matching unit 38 matches an impedance of the RF power supply source 37 to an impedance of the load, e.g., the process vessel 120. An electrostatic chuck 41 is provided on an upper surface of the substrate holder 140 for holding the substrate by an electrostatic absorption power, via a DC power supply source 46.

The plasma processing device 30 further includes a reaction gas supply part 13. An enlarged view of the reaction gas supply part 13 is also shown in FIG. 3. As shown in this figure, the reaction gas supply part 13 may include a base injector 61 located at a backward position, inside the dielectric window 160, compared to a lower surface 63 of the dielectric window 160. The reaction gas supply part 13 further includes a base holder 64 which penetrates through the dielectric window 160 in a thickness direction to hold the injector base 61. A plan view of the injector base 61 is also shown in FIG. 3. As shown in this figure, a plurality of supply holes 66 are provided on a flat wall surface 67 which is positioned opposite to the substrate holder 140. The plurality of supply holes 66 are positioned radially at a centre of the flat wall surface 67.

The reaction gas supply part 13 further includes a gas duct 68. As shown in FIG. 3, the gas duct 68 penetrates, respectively, through a central conductor 25 from the coaxial waveguide 24, the radial line slot plate 300, and the dielectric window 160, to reach the plurality of supply holes 66. A gas supply system 72 is connected to a gas entrance hole 69 formed at an upper end of the central conductor 25. The gas supply system 72 may include an on-off valve 70 and a flow rate controller 71, e.g., a mass flow controller.

Further, the reaction gas may be supplied into the process vessel 120 by two more gas ducts 89 provided on cylindrical sidewall 18. It should be noted that the reaction gas is at least any one of a plasma excitation gas and a material gas. By adjusting the flow rate of the reaction gas supplied from the gas ducts 68 and 89, an optimized dissociation of the material gas may be achieved within the process vessel 120.

### Line-Width or CD Measurement Device:

A line width of the resist pattern 16c, the silicon-contained anti reflective coating (Si-ARC) layer 16b, the organic dielectric layer (ODL) 16a or the silicon nitride (SiN) layer 14 is measured and calculated using the line width measurement device. This device may be any one of a stand-alone type, one that is integrated into a coater developer, which is called an IM (integrated metrology), or one that is integrated into an etching device. When the line width measurement device is built into the coater developer, a latent image of a resist or a line width of a resist after development can be measured immediately after processing. When the line width measurement device is built into the etching device, the line width can be measured before etching and after etching as well. On the other hand, the line-width or CD measurement may be conducted using a standalone measurement system. In what follows, each of the above-mentioned embodiments will be explained individually in detail.

1) Line-Width Measurement Device Integrated into a Coater Developer:

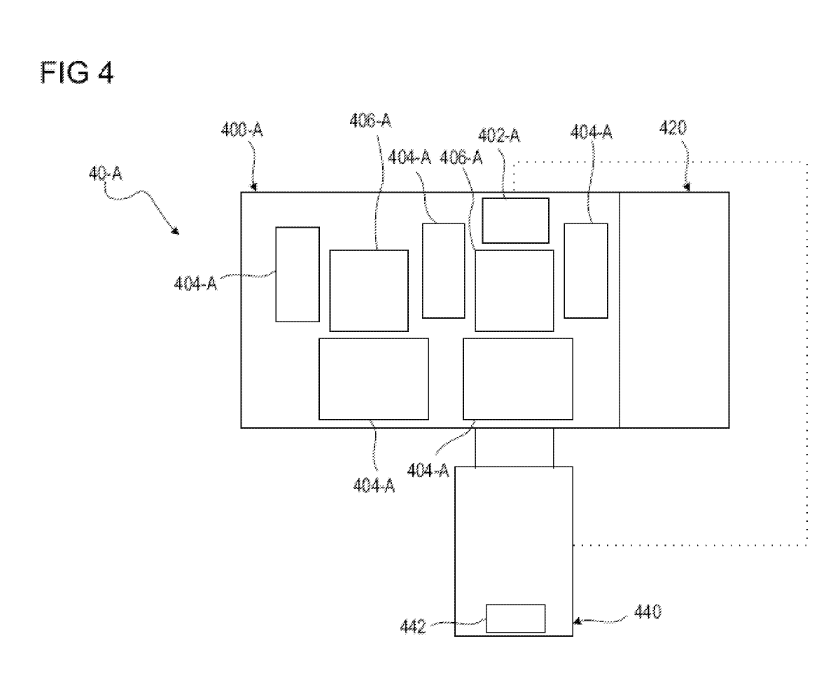

FIG. 4 illustrates a schematic diagram of an embodiment of a line-width measurement device 402-A integrated into an entire structure of a photo resist forming device 40-A. For the sake of convenience, the entire structure of the photo resist forming apparatus 40-A is simplified. As shown in FIG. 4, the entire structure of the photo resist forming apparatus 40-A may include a coater developer 400-A and an exposure apparatus 420. The coater developer 400-A is attached to the exposure apparatus 420, which can be, in turn, connected to the etching device 440.

The photo resist forming apparatus 40-A may include a line-width measurement device 402-A, a plurality of processing units (coating units or developing units) 404-A, and two substrate transfer units 406-A. The plurality of processing units 404-A may further include coating units and/or developing units. The substrate transfer units 406-A have a function of carrying substrates between different adjacent parts in the entire structure of the photo resist forming device 40-A. Further, the substrate transfer units 406-A are structured to be movable upward/downward and back/forth and can be rotated around a vertical axis.

A line-width or critical dimension (CD) of a resist pattern is measured after performing a developing process. In the next step, appropriate setting conditions such as, for example, a flow rate of the etching gas is calculated based on the measured line-width. Then, the appropriate setting conditions are feed-forwarded to the etching device 440 from the coater developer 400-A. In some embodiments the measured raw data may be transmitted from the coater developer 400-A to the etching device 440 and processed to obtain appropriate etching conditions. In these embodiments, the appropriate setting conditions are calculated by the measured raw data using a process condition database, not shown in this figure. The process condition database stores various processing conditions in a memory of computer 442.

2) Line-Width Measurement Device Integrated into the Etching Device:

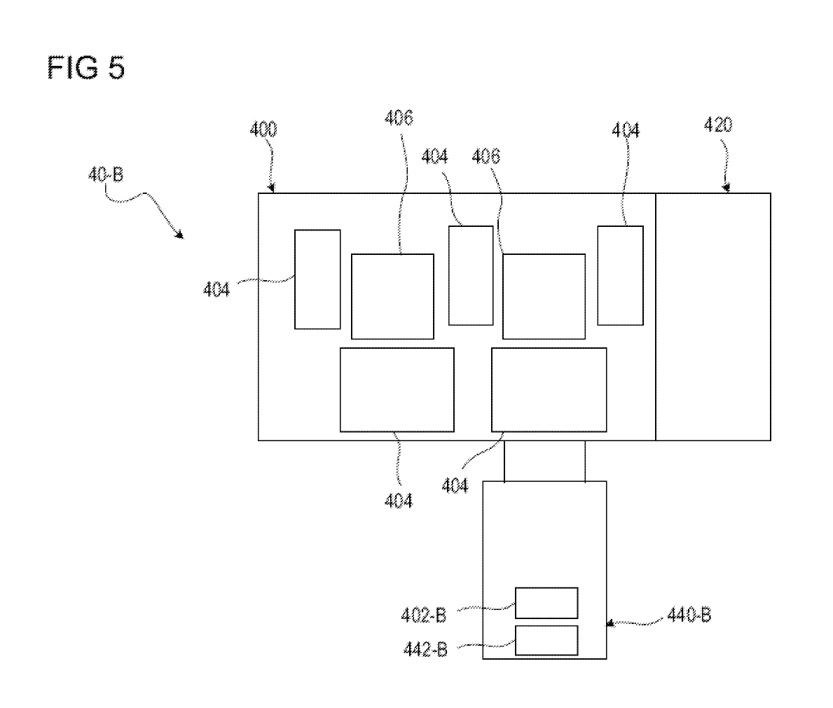

With reference to FIG. 5, a schematic diagram of an embodiment of an entire structure of a photo resist forming device 40-B is shown. As shown in this figure, the entire structure of the photo resist forming device 40-B is different form the structure of 40-A in that the line-width measurement device 402-B is integrated into the etching device 440-B, instead of being integrated into the coater developer 400. The other components are basically the same as the structure of 40-A. In this embodiment, all three control methods including: 1) the feed-forward control process, 2) the feed-back control process, and 3) the dynamic (in-situ) control process may be used for controlling the substrate pattern.

In the feed-forward control process, after transferring a developed substrate into the etching device 440-B, a line-width of the resist pattern is measured by the line-width measurement device 402-B in the etching device 440-B and appropriate setting conditions such as, for example, a flow rate of the etching gas is calculated based on the measured line-width. Then, the appropriate setting conditions are adjusted in the etching device 440-B for the etching process.

In the feed-back control process, a line-width of an etched pattern is measured by the line-width measurement device 402-B and appropriate setting conditions such as, for example, a flow rate of the etching gas is calculated based on the measured line-width. Therefore, the etching process for another substrate can be optimized by performing the etching process under the appropriate setting conditions.

In the dynamic (in-situ) control process, a line-width of an etched pattern is measured by the line-width measurement device 402-B and appropriate setting conditions such as, for example, a flow rate of the etching gas is adjusted dynamically during the etching process. It should be understood that in all the above-mentioned control process, the appropriate setting conditions are calculated by the measured raw data using a process condition database, not shown in FIG. 5, which stores various processing conditions in a memory of computer 442-B.

According to one aspect of the present invention, a multilayer structure may need to be etched consecutively. In this embodiment, a line-width of a first patterned layer is first measured. Then, appropriate etching conditions are set for a second layer which is formed beneath the first layer. In the next step, the second layer is etched using the optimized etching conditions. Thereafter, a line-width of the second etched layer is measured, and then appropriate etching conditions are set for a third layer. This process may continue for the number of layer in the multilayer structure. In this way, the line-width (CD value) of the final etched pattern is closer to the desired target value. The measurement of the line-width (CD value) may be performed by either an IM module equipped outside a chamber or a line width measurement device equipped in the chamber. With this line width measurement device equipped with etch chamber, the CD can be measured after main etching (ME) process and preferred etching conditions for over etching (OE) process can be adjusted to control CD precisely.

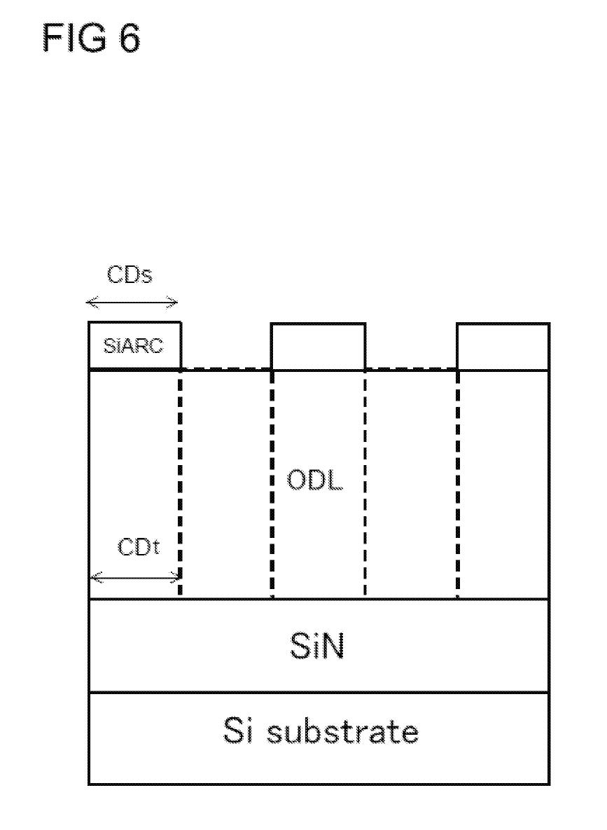

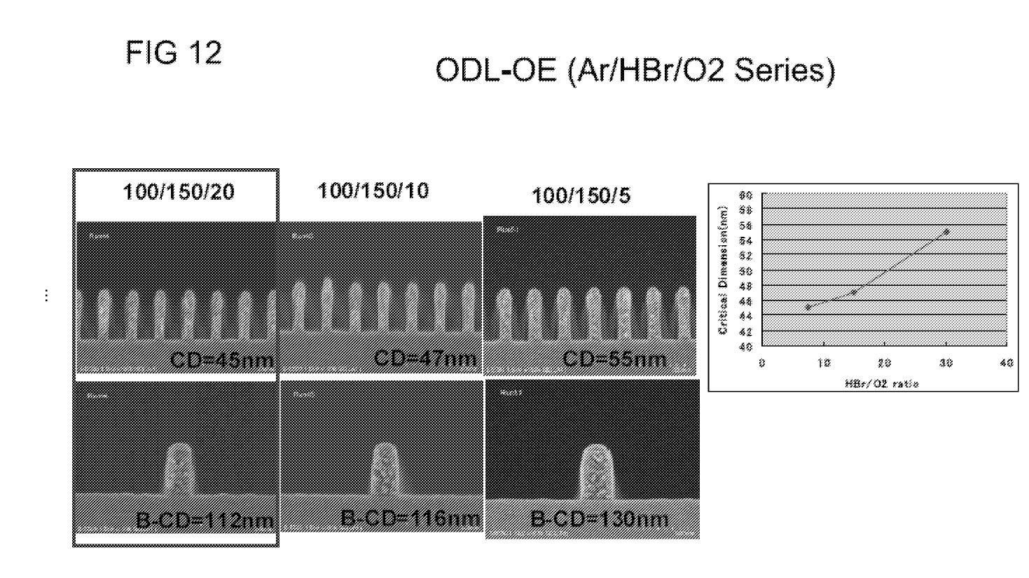

As an example, the target structure 10 as shown in FIG. 1 may be considered as the multilayer structure. To perform the etching process of each layer according to the process described in paragraph [0052], the following process may be understood with reference to the structure of (FIG. 6): First, a CD deviation value per unit time (ΔCD) is obtained for a plurality of HBr/O₂ ratios (conditions) (shown in FIG. 12) and stored as a table. Second, a line-width of the Si-ARC layer 16b (CDs) is measured. In the third step, the difference between the measured Si-ARC line-width (CDs) and the line-width target value (CDt) is calculated (CDt-CDs). At last, an optimized flow rate of HBr/O₂ ratio is obtained based on the difference (CDt-CDs) and a time period for over etching (OE) of ODL layer (T), which is obtained in advance for the ODL etching process. The etching is then performed under the optimized HBr/O₂ flow rate. In this way, the final ODL pattern 16a is obtained in a shape close to the target line-width (CDt). Note that in a case where the Si-ARC layer 16b is etched using the photo resist mask 16c, a flow rate of CF₄/CHF₃ is optimized according to the above-mentioned process and the etching is performed under the optimized CF₄/CHF₃ flow rate. CD value can also be adjusted by etching time with a certain etching conditions (e.g. etching gas flow rate). Further, CD value can be changed by adjusting both flow ratio (flow arte) of the etching gases and etching time.

When the difference between the target CDt value and the measured line width of a resist pattern on the Si-ARC layer 16b exceeds a predetermined threshold amount (that is trim capability), flow rate ratios (HBr/O2 and CF4/CHF3 ratios in this specific example) may be optimized in order to obtain the target CDt value when completing both Si-ARC and ODL layers. The predetermined threshold amount may be obtained when one skilled in the art estimates that the target value cannot be reached by the end of the Si-ARC etching process comparing measured resist CD and the target CD value before initiating etching. In this way, the target value for the line-width may be reached when the etching process of two consecutive layers of Si-ARC and ODL are finished. In this embodiment, the flow rate of HBr/O2 and CF4/CHF3 ratios are determined by taking into account various parameters such as, the etching time and the etching shape of each respective layer. In this embodiment, the target value of Si-ARC line-width and the target value of ODL line-width are provided beforehand.

### 3) Stand-Alone Line-Width Measurement Device

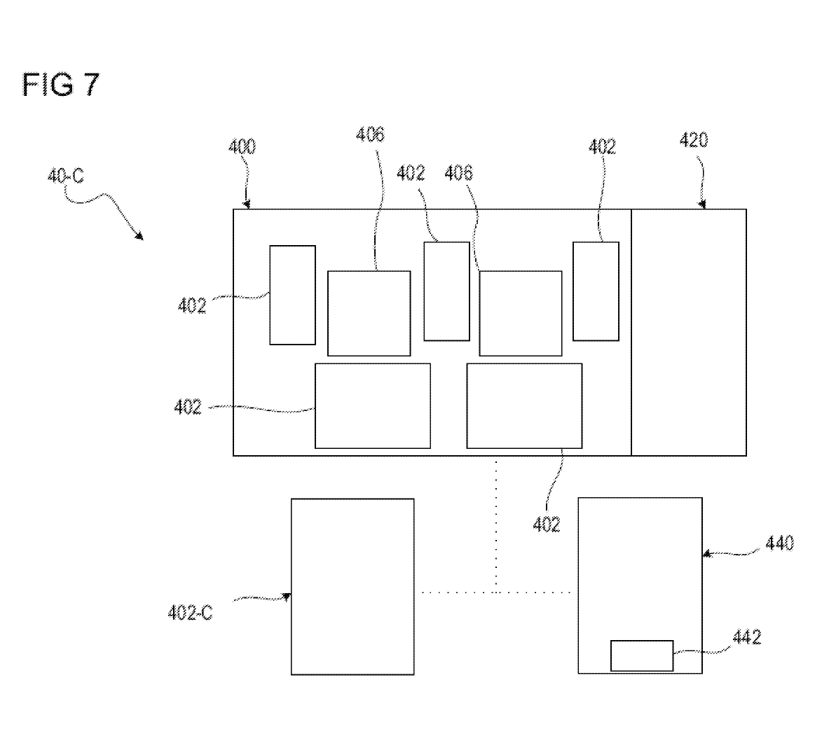

FIG. 7 illustrates a schematic diagram of an embodiment of a stand-alone line-width measurement device 402-C of an entire structure of a photo resist forming device 40-C. As shown in this figure, the entire structure of the photo resist forming device 40-C is different from the structure of 40-A and 40-B in that the line-width measurement device 402-C is not integrated into any device and functions as a stand-alone measurement device. The other components are basically the same as the structure of 40-A. In this embodiment, a substrate container (generally called FOUP), not shown in FIG. 7, is used. Each substrate may be transported to the container after the developing process or after the etching process and transferred to the line width measurement device 402-C using for example, an automated guided vehicle (AGV). In each substrate, a line-width of each substrate is first measured and then appropriate setting conditions are calculated. The measured CD value and the appropriate setting conditions are transmitted to the etching device 440.

### Experimental Samples

In order to evaluate the effect of hydrogen bromide (HBr) on side wall protection mechanism and also to establish a process for controlling critical dimension (CD), several experimental samples are manufactured with the same target structure as the one described in FIG. 1 or FIG. 2. The experimental samples are then subjected to the plasma etching process according to the present invention in which appropriate amount of hydrogen bromide (HBr) is added into the mixed atmosphere of nitrogen and oxygen (N₂/O₂) during the over etching (OE) step of organic dielectric layer (ODL). In the following the results of these evaluations will be explained in detail.

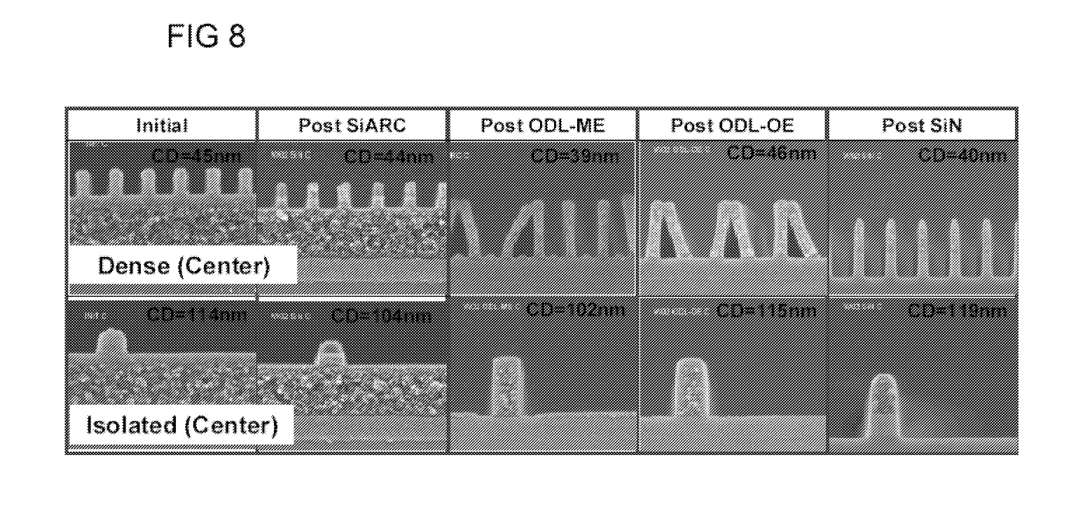

With reference to FIG. 8, cross-sectional view of two experimental samples are shown after performing the plasma etching process at each specific layer of their target structure. The first experimental sample features a dense or nested array pattern while the second experimental sample represents an isolated pattern. Cross-sectional views of both patterns are shown respectively on the upper and lower side of the FIG. 8. As shown in this figure, the cross-sectional views are taken after performing the etching step for each mask layer. For both experimental samples, columns 1-5 of these cross-sectional views correspond respectively to resist pattern, Si-ARC pattern, ODL main etching (ME) pattern, ODL over etching (OE) pattern, and the hard mask SiN pattern. Table I summarizes the etching conditions applied to each mask layers.

TABLE I
Etching conditions used for experimental samples

| | Press. | N2 | O2 | HBr | CF4 | CHF3 | MW | RF | Time |
|---|---|---|---|---|---|---|---|---|---|
| | (mTorr) | (sccm) | (sccm) | (sccm) | (sccm) | (sccm) | (W) | (W) | (sec) |
| Si-ARC | 100 | — | — | — | 180 | 180 | 2000 | 300 | 15 |
| ODL | 10 | 400 | 20 | — | — | — | 3000 | 200 | 36 |
| (ME) | | | | | | | | | |
| ODL | 10 | 400 | 4 | 60 | — | — | 3000 | 200 | 30 |
| (OE) | | | | | | | | | |
| SiN | 70 | — | — | — | 150 | 170 | 2000 | 300 | 28 |

As shown in FIG. 8, the critical dimension (CD) decreases in the Si-ARC and ODL main etching (ME) step. By adding hydrogen bromide (HBr) into the mixed atmosphere of nitrogen and oxygen (N₂/O₂) during the over etching (OE) step of the ODL layer, the critical dimension of both dense and isolated patterns may increase. As shown in FIG. 8, the critical dimension (CD) of the dense array pattern in the ODL over etching (OE) layer is about 46 nm while the critical dimension (CD) of the isolated pattern is about 115 nm in the same layer. It is thought that this increase of the critical dimension (CD) is attributed to the deposition of a thin carbon bromide (CBrₓ) layer, which functions as a side wall protection against etching.

The final critical dimension (CD), after performing the hard mask SiN etching step, is 40 nm for the dense pattern and 119 nm for the isolated pattern. A trim capability is a range the critical dimension (CD) of a mask layer thickens or thins after performing an etching step by adjusting gas flow conditions (gas ratio, total flow rate, etc.). FIG. 8 shows that CD value changed both in dense (nested) pattern and in isolated pattern.

In what follows the effect of each parameter such as, for example, the HBr flow rate, the time dependency of over etching (OE) step, the etching gas type and composition ratio, on the critical dimension (CD) of the ODL layer is investigated. For this purpose, various experimental samples with dense (nested) and isolated patterns are formed under different etching conditions. Unless described otherwise below, the following etching conditions are used to pattern the ODL layers of each experimental samples: 1) main etching (ME) conditions; a pressure of 10 mTorr, a N₂/O₂ flow rate of 400 sccm/20 sccm, a microwave power of 3 kW, an RF power of 200 W, and main etching (ME) period of 40 seconds, and 2) over etching (OE) conditions: a pressure of 10 mTorr, a N₂/O₂ flow rate of 400 sccm/4 sccm, a microwave power of 3 kW, and an RF power of 200 W.

To evaluate the dependency of critical dimension (CD) on the over etching time period, two set of experimental samples are manufactured. In each set, three experimental samples with the same mask pattern are formed. Similar to the previous case, the first set of experimental samples features a dense array pattern while the second set of experimental samples represents an isolated pattern. The main etching (ME) and over etching (OE) of the ODL layer is performed in the plasma processing device 30. The main etching (ME) and over etching (OE) conditions used for patterning the ODL layer are the same as those described in paragraph [0060]. For this evaluation, the HBr flow rate is set to 60 sccm. Further, in each set, three experimental samples are patterned under the following over etching (OE) time treatment: 0, 20, and 40 seconds.

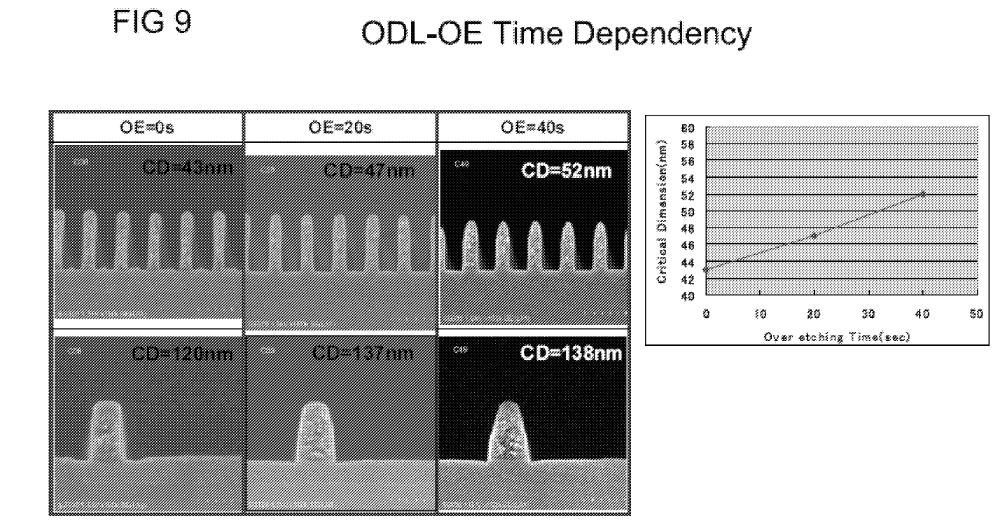

FIG. 9 represents the cross-sectional views of experimental samples and their critical dimension (CD) as a function of over etching (OE) time treatment. As shown in this figure, the critical dimension (CD) can be made thicker by extending the over etching (OE) time treatment. It is thought that this is mainly due to the fact that the extension of over etching (OE) time period, increases the deposition of the reactive by product, e.g., carbon bromide (CBrₓ), over the ODL pattern.

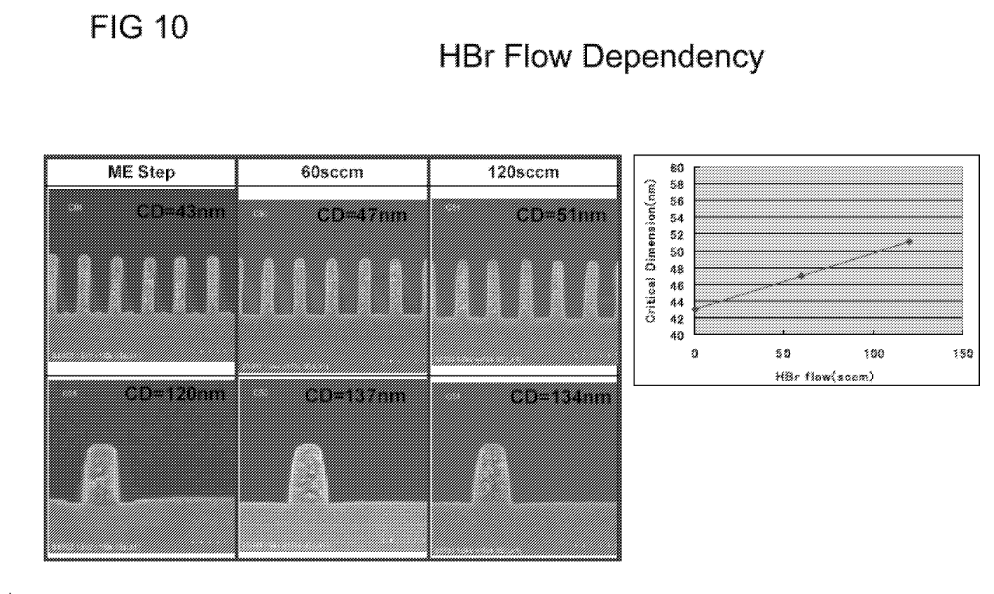

Referring next to FIG. 10, cross-sectional views of experimental samples and their critical dimension (CD) as a function of HBr flow rate are shown. Similar to the previous embodiment, two set of experimental samples, each having three samples with similar patterns, are formed. The first set of experimental samples features a dense (nested) array pattern while the second set of experimental samples represents an isolated pattern. The main etching (ME) and over etching (OE) of the ODL layer is performed in the plasma processing device 30. The main etching (ME) and over etching (OE) conditions used for patterning the ODL layer are the same as those described in paragraph [0060]. For this evaluation, the over etching (OE) time treatment condition is all set to 20 seconds. Further, each of the three experimental samples of each set are, respectively, patterned under the following HBr flow rate condition: 0 sccm, 60 sccm, and 120 sccm.

As shown in FIG. 10, the critical dimension (CD) increases with the increase in the HBr flow rate. The mechanism used to control the critical dimension (CD) of ODL layer is thought as follows: by adding hydrogen bromide (HBr) into the mixture of nitrogen and oxygen (N₂/O₂), hydrogen (H) reduces oxygen (O) in the surface of the ODL layer. In other words, oxygen (O) atoms are extracted from the ODL. As a result, an organic dielectric layer (ODL) with high carbon content in its surface is created. So carbon-carbon bonds increase, which makes the organic dielectric layer (ODL) more rigid. The rigidness of ODL layer functions as a side wall protection, which results in prevention of etching.

On the other hand, it is also thought that the high carbon content of the ODL layer increases bromide-carbon bonds near the surface of the ODL pattern. It can also be said that a thin layer of carbon bromide (CBrₓ) deposited over the ODL pattern functions as a side wall protection, which results in prevention of etching. By increasing the hydrogen bromide (HBr) flow rate, the deposition of carbon bromide (CBrₓ) increases due to increase of Br species, which leads, in turn, to increase the ODL's critical dimension (CD). On the other hand, by decreasing HBr flow rate, CD thickening becomes smaller. In this way, a better controllability for obtaining a predetermined value of critical dimension (CD) can be achieved.

The critical dimension (CD) of ODL layer may be controlled using other type of etching gas, such as chlorine (Cl₂) gas. To evaluate how another type of etchant gas may affect the controllability of the critical dimension (CD), two set of experimental samples are manufactured. In each set, two experimental samples with the same mask pattern are formed. Similar to the previous embodiments, the first set of experimental samples features a dense array pattern while the second set of experimental samples represents an isolated pattern. In each set, the first and second experimental samples are first subjected to a main etching (ME) step under the same etching conditions as those described in paragraph [0060]. The first experimental sample of each set is then subjected to an over etching (OE) step by adding hydrogen bromide (HBr) gas into the mixture of nitrogen and oxygen (N₂/O₂). However, the second experimental sample of each set is subjected to an over etching step by adding chlorine (Cl₂) into the mixture of nitrogen and oxygen (N₂/O₂). For this evaluation, both HBr and Cl₂ flow rates are set to 60 sccm. Further, the over etching (OE) time treatment condition is set to 20 seconds in each experimental set.

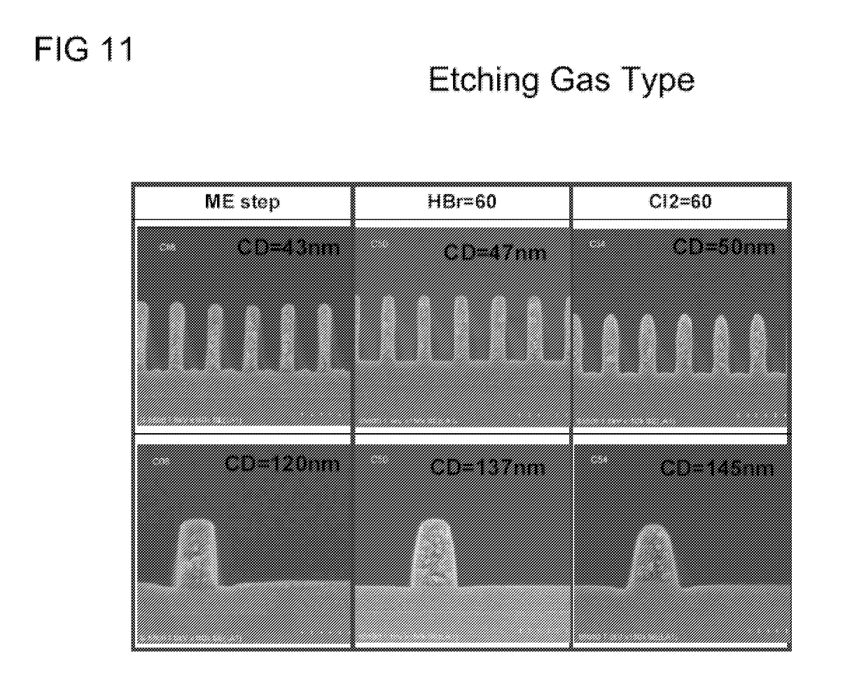

FIG. 11 illustrates cross-sectional views of experimental samples for various etching gas type. As shown in this figure, the critical dimension (CD) of the ODL layer in the over etching (OE) step, is increased compared to the main etching (ME) step, for both etching gas type (HBr and Cl₂). Although the exact mechanism for controlling the critical dimension (CD) of the ODL layer in the case of chlorine (Cl₂) gas is unknown, the similar results are obtained with regards to the increase of critical dimension (CD). However, in this embodiment, some other adverse effects are observed. For example, the underlying hard mask silicon nitride (SiN) layer is shaved such that the height of its mask is decreased (tapered shape).

In an alternative embodiment, the desired critical dimension (CD) is carried out by adding hydrogen bromide (HBr) into a mixed atmosphere of argon and oxygen (Ar/O₂). In this alternative embodiment, the argon oxygen (Ar/HBr/O₂) series are used to perform the ODL main etching (ME) step. Similar to the previous embodiments, two set of experimental samples each having three samples with similar patterns are formed. The first set of experimental samples features a dense array pattern while the second set of experimental samples represents an isolated pattern. More specifically, a small piece of a substrate (cleaved substrate, also called a coupon) having the structure shown in FIG. 1 is used in this experiment. When the Si-ARC and the ODL main etching (ME) are performed, the coupon is attached on a substrate on which a photo resist is totally coated. When the ODL over etching (OE) is performed, the coupon is attached on another substrate on which a silicon nitride (SiN) is totally deposited. The ODL over etching (OE) is performed for 15 seconds. Table II summarizes the etching conditions at Si-ARC and ODL layers.

TABLE II
Etching conditions used for experimental samples

| | Press. | Ar | HBr | O2 | CF4 | CHF3 | MW | RF | Time |
|---|---|---|---|---|---|---|---|---|---|
| | (mTorr) | (sccm) | (sccm) | (sccm) | (sccm) | (sccm) | (W) | (W) | (sec) |
| Si-ARC | 100 | — | — | — | 150 | 210 | 2000 | 300 | 15 |
| ODL | 10 | 100 | 150 | 50 | — | — | 1500 | 200 | 51 |
| (ME) | | | | | | | | | |

After performing the Si-ARC and ODL main (ME) etching steps, an over etching (OE) step is performed using the plasma processing device 30. The over etching (OE) step of the first, second, and third experimental samples of each set are conducted respectively under the following Ar/HBr/O₂ flow rate: 100/150/20, 100/150/10, and 100/150/5 sccm.

Referring next to FIG. 12, cross-sectional views of experimental samples and their critical dimension (CD) as a function of HBr/O₂ ratio are shown. As shown in this figure, the critical dimension (CD) of ODL layer increases with the increase in the HBr/O₂ ratio. In other words, the critical dimension (CD) of ODL layer increases when the oxygen (O₂) flow rate decreases.

In the conventional plasma etching process, there has been a problem in that after performing the etching step there exist some variation in pattern shape. In order to avoid this variation in pattern shape, a mask for photolithography purposes is designed by taking into account the variation in the dimension of finished etched pattern. However, the above-mentioned problem cannot be fully avoided by this solution.

The plasma etching process of the present invention provides a solution for the above-mentioned problem. By adding hydrogen bromide (HBr) into the mixture of N₂/O₂or Ar/O₂, it is thought that hydrogen (H) reduces oxygen (O) in the surface of the ODL layer. In other words, oxygen (O) atoms are extracted from the ODL layer. As a result, an organic dielectric layer (ODL) with high carbon content in its surface is created. So carbon-carbon bonds increase, which makes the organic dielectric layer (ODL) more rigid. The rigidness of ODL layer functions as a side wall protection, which results in prevention of etching.

In addition, it is also thought that the high carbon content of the ODL layer increases a plurality of bromide-carbon bonds near the surface of the ODL pattern. As a result, a thin layer of carbon bromide (CBrₓ) is deposited over the ODL pattern, which functions as a side wall protection. Therefore, the lateral etching direction of ODL layer may be suppressed. Further, by increasing the hydrogen bromide (HBr) flow rate, the deposition of carbon bromide (CBrₓ) increases due to increase of Br species, which increases the ODL's critical dimension (CD). On the other hand, by decreasing HBr flow rate, then CD thickening rate becomes smaller. In this way, a better controllability for obtaining a predetermined value of critical dimension (CD) can be achieved by selecting appropriate HBr flow rate.

To evaluate the variation of pattern shape and their critical dimension uniformity, two set of experimental samples, each having different patterns (dense, also called “nested”, pattern and isolated pattern), are manufactured. In each set, two experimental samples with similar patterns are formed. Table III summarizes the etching conditions used in each mask layers of experimental samples.

TABLE III
Etching conditions used for experimental samples

| | Ar | HBr | O2 | N2 | CF4 | CHF3 | Press. | MW | |
|---|---|---|---|---|---|---|---|---|---|
| | (sccm) | (sccm) | (sccm) | (sccm) | (sccm) | (sccm) | (mTorr) | (W) | RF (W) |
| Si-ARC | — | — | — | — | 180 | 180 | 100 | 3000 | Ignition |
| | — | — | — | — | 180 | 180 | 100 | 2000 | 300 |
| ODL | 250 | 150 | 40 | — | — | — | 10 | 3000 | Ignition |
| (ME) | 250 | 150 | 40 | — | — | — | 10 | 2000 | 250 |
| ODL | | 60 | 4 | 400 | — | — | 10 | 3000 | Ignition |
| (OE) | | 60 | 4 | 400 | — | — | 10 | 3000 | 200 |

For this experiment, the etching time in the Si-ARC and ODL main etching (ME) step are set, respectively, to 16 and 40.8 seconds. In the over etching (OE) step, the etching time for one experimental sample is set to 20 seconds while the etching time for other experimental sample is set to 40 seconds.

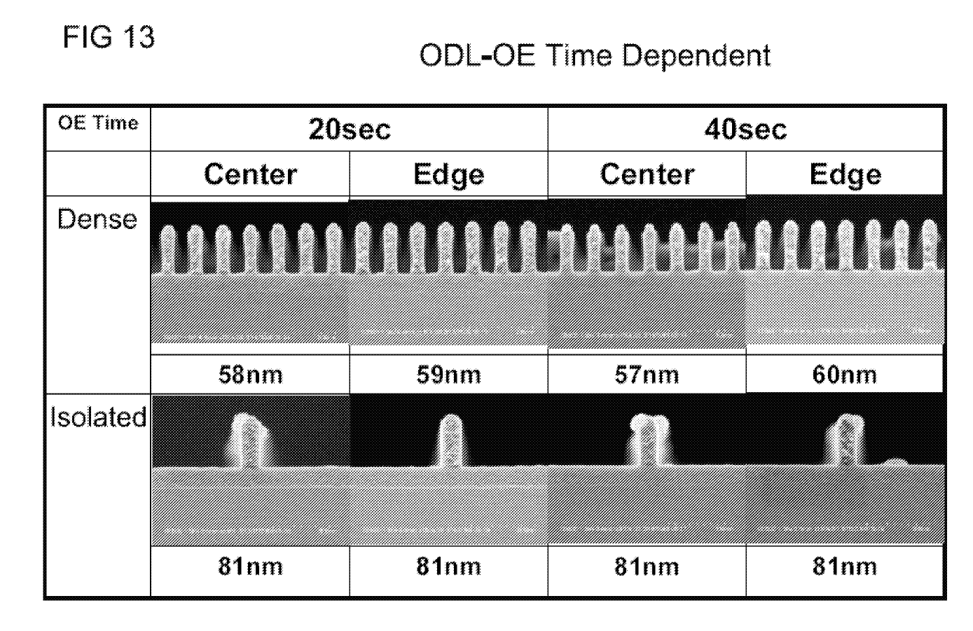

FIG. 13 illustrates cross-sectional views of experimental samples and their critical dimension (CD). For each experimental sample, the cross-sectional views are taken, respectively, along the center and edge of the substrate, which are defined as “Center” and “Edge” on FIG. 13. As shown in this figure, the critical dimension (CD) does not depend on the over etching (OE) time treatment for all experimental samples. In addition, no variation in pattern shape is observed across all samples.

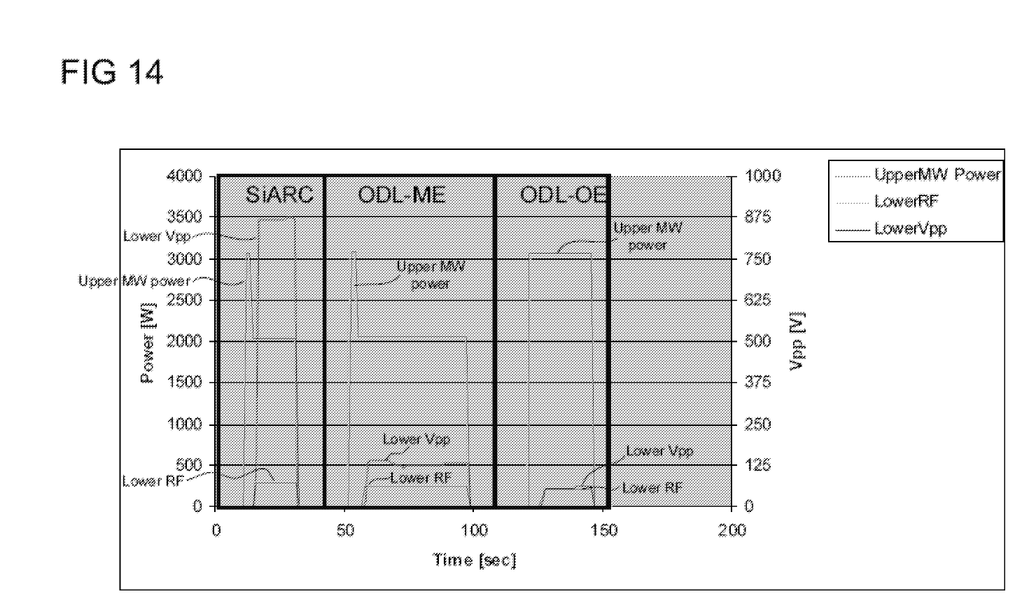

FIG. 14 illustrates the microwave power, RF power, and RF voltage of each mask layer as a function of time. The horizontal axis represents process time, the left vertical axis represents microwave power and RF bias power while the right vertical axis represents RF bias voltage. The data of this experiment, shown in FIG. 14, represents an example in which the etching step for a multilayer structure is performed consecutively in the same process vessel 120 of the plasma processing device 30. It should be noted that the upper microwave power at the beginning of each process step is applied as a δ (delta) function to ignite the plasma generation process.

The RF bias voltage (Lower Vpp) is applied to the substrate holder 140 from the plasma processing device 30 (please refer to FIG. 3). As described previously, this RF bias voltage controls ions energy drawn to the substrate. As shown in FIG. 14, the RF bias voltage drops as the etching process proceeds to the next mask layer. Thereby, the energy of the ions contacting the substrate decreases as the etching process moves forward toward the lower mask layers.

Further, another problem observed in the conventional plasma etching process that the resist patterns are formed nonuniformly depending on a region where patterns are isolated or dense (nested). In other words, there exist some variations in pattern shape depending upon whether the resist pattern is isolated, also called roughness, or nested, also called fineness. To avoid the variation in shape of roughness and fineness, a mask for photolithography purposes is designed by considering these variations. However, the above-mentioned problem cannot be fully avoided by this solution. It has also been observed that the variation in shape of roughness and fineness occurs when controlling the critical dimension (CD).

The variation in shape of roughness and fineness may be avoided while patterning the silicon-contained anti reflective coating (Si-ARC) layer according to the process of present invention. In this embodiment, the line-width or the critical dimension (CD) of the final pattern, e.g., the hard mask SiN, is controlled through the Si-ARC layer by adjusting a ratio of tetrafluoromethane to trifluoromethane (CF₄/CHF₃) gas. By adjusting the ratio of CF₄/CHF₃ in the Si-ARC etching step, the critical dimension of Si-ARC pattern may be thickened or thinned such that the final critical dimension (CD) may be controlled within a range of about −2 nm to +10 nm.

The Si-ARC pattern is mainly composed of silicon (Si) and carbon (C) atoms. It is thought that the carbon content of the Si-ARC layer helps to generate a plurality of carbon-fluorine bonds on the surface of the Si-ARC layer. Therefore, by adjusting the ratio of CF₄/CHF₃ in the Si-ARC layer, a thin layer of CFₓ series film is deposited over the Si-ARC pattern, due to the bond energy difference between CF₄ gas and CHF₃ gas. As a result, the lateral etching direction of Si-ARC layer may be suppressed and the critical dimension (CD) of the Si-ARC pattern may increase, according to the process of present invention, by adjusting the ratio of CF₄/CHF₃ in the Si-ARC etching step.

To evaluate the controllability of the critical dimension (CD) through the etching step of Si-ARC layer and also to investigate the variation in shape of roughness and fineness, various experimental samples are manufactured. Similar to the previous embodiments, two experimental samples, each having different patterns (dense pattern and isolated pattern), are formed. Table IV summarizes the etching conditions used in each mask layers of experimental samples. For this experiment, the etching time in the Si-ARC, ODL main etching (ME) step, ODL over etching (OE) step, SiN, and ashing step are set, respectively, to 17.7, 40.8, 20, and 30 seconds. Further, the ratio of CF₄/CHF₃ is set to 1 (180/180).

TABLE IV
Etching conditions used for experimental samples

| | Ar | HBr | O2 | N2 | CF4 | CHF3 | Press. | MW | |
|---|---|---|---|---|---|---|---|---|---|
| | (sccm) | (sccm) | (sccm) | (sccm) | (sccm) | (sccm) | (mTorr) | (W) | RF (W) |
| Si-ARC | — | — | — | — | 180 | 180 | 100 | 3000 | Ignition |
| | — | — | — | — | 180 | 180 | 100 | 2000 | 300 |
| ODL | 250 | 150 | 40 | — | — | — | 10 | 3000 | Ignition |
| (ME) | 250 | 150 | 40 | — | — | — | 10 | 2000 | 250 |
| ODL | — | 60 | 4 | 400 | — | — | 10 | 3000 | Ignition |
| (OE) | — | 60 | 4 | 400 | — | — | 10 | 3000 | 200 |
| SiN | — | — | — | — | 150 | 170 | 70 | 3000 | Ignition |
| | — | — | — | — | 150 | 170 | 70 | 2000 | 300 |
| Ash | — | — | 370 | — | — | — | 50 | 3000 | Ignition |
| | — | — | 370 | — | — | — | 50 | 2000 | 0 |

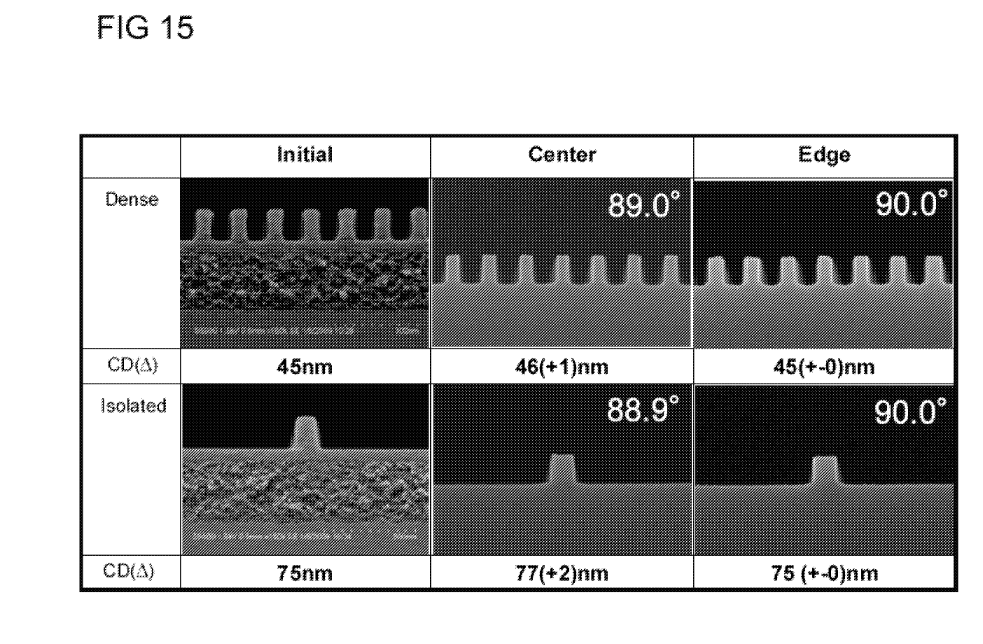

With reference to FIG. 15, cross-sectional views of experimental samples and their critical dimension (CD) are shown. As shown in FIG. 15, the vertical profiles are very close to 90 degrees across all experimental samples, showing almost no variation in shape of roughness and fineness. In addition, the critical dimension (CD) of Si-ARC patterns show minimal deviation (±0 nm to +2 nm) from the desired target pattern across all experimental samples. In this experiment, the desired target pattern for both dense and isolated patterns are set respectively to 45 nm and 75 nm.

The controllability of the critical dimension (CD) through the etching step of Si-ARC layer and also the variation in shape of roughness and fineness are also investigated when the ratio CF₄/CHF₃ varies for each experimental sample. Again, two set of experimental samples, each having different patterns (dense pattern and isolated pattern), are manufactured. In each set, three experimental samples are formed. The etching conditions used in each mask layers of experimental samples are the same as those summarized in Table IV. However, in each set of experimental sample, the ratio of CF₄/CHF₃ is set respectively to (210/150), (180/180), and (150/210) for the first, second, and third experimental samples.

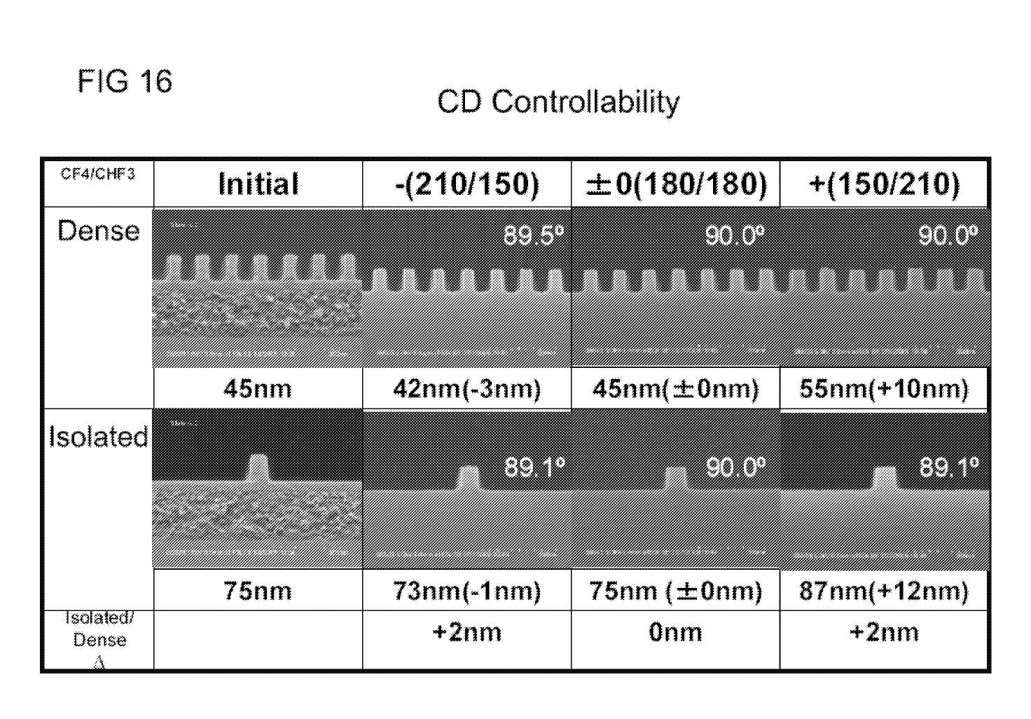

Referring next to FIG. 16, cross-sectional views of experimental samples and their critical dimension (CD) are shown. As shown in this figure, the vertical profiles are very close to 90 degrees across all experimental samples, showing almost no variation in shape of roughness and fineness. In addition, the critical dimension (CD) of Si-ARC patterns show minimal deviation (−3 nm to +12 nm) from the initial target pattern across all experimental samples. The maximum deviation across the patterns is +2 nm. In this experiment, the initial target pattern for both dense and isolated patterns is set respectively to 45 nm and 75 nm.

While the principles of the disclosure have been described above in connection with specific apparatuses/devices and methods, it is to be clearly understood that this description is made only by way of example and not as limitation on the scope of the invention.

What is claimed is:

1. A method for processing a substrate to form a desired pattern by an etching process after forming a mask pattern over the substrate, the method comprising the steps of:
forming two layers over the substrate, the two layers comprising a silicon nitride layer and an organic dielectric layer;
measuring a width of the mask pattern or an etched pattern of one of the two layers; and
adjusting a flow rate of any one of HBr and other gases based on the measured width, HBr and the other gases being used in the etching process.

2. The method as recited in claim 1, further comprising a step of etching one of the two layers of the same substrate under the adjusted flow rate based on the measured width of the mask pattern.

3. The method as recited in claim 1, further comprising a step of etching one of the two layers of another substrate under the adjusted flow rate based on the measured width of the mask pattern or the etched pattern.

4. The method as recited in claim 1, further comprising a step of etching one of the two layers of the same substrate under the adjusted flow rate based on the measured width of the etched pattern, wherein the measuring step and the adjusting step are performed during the etching process.

5. The method as recited in claim 1, wherein the adjusting step comprises increasing a flow rate ratio of HBr to the other gases when the measured width is smaller than a desired width and decreasing the flow rate ratio of HBr to the other gases when the measured width is greater than the desired width.

6. The method as recited in claim 2, wherein the organic dielectric layer is etched in the etching step.

7. The method as recited in claim 6, wherein the adjusting step comprises increasing an etching time when the measured width is smaller than a desired width and decreasing the etching time when the measured width is greater than the desired width.

8. The method as recited in claim 6, wherein the etching step includes a main etching and an over etching following the main etching, and the HBr is used in the over etching.

9. The method as recited in claim 8, wherein the adjusting step comprises increasing an over etching time when the measured width is smaller than a desired width and decreasing the over etching time when the measured width is greater than the desired width.

10. The method as recited in claim 1, wherein the adjusting step comprises increasing a RF bias power applied to the substrate when the measured width is smaller than a desired width and decreasing the RF bias power when the measured width is greater than the desired width.

11. The method as recited in claim 1, wherein the other gases comprises N₂ and O₂.

12. The method as recited in claim 1, wherein the other gases comprises Ar and O₂.

13. A method for processing a substrate to form a desired pattern by an etching process after forming a mask pattern over the substrate, the method comprising the steps of:
forming three layers over the substrate, the three layers comprising a silicon nitride layer, an organic dielectric layer and a silicon-contained anti-reflective coating layer;
measuring a width of the mask pattern or an etched pattern of one of the three layers; and
adjusting a flow rate of any one of CF₄ and CHF₃ based on the measured width, CF₄ and CHF₃ being used in the etching process.

14. The method as recited in claim 13, further comprising a step of etching one of the three layers of the same substrate under the adjusted flow rate based on the measured width of the mask pattern.

15. The method as recited in claim 13, further comprising a step of etching one of the three layers of another substrate under the adjusted flow rate based on the measured width of the mask pattern or the etched pattern.

16. The method as recited in claim 13, further comprising a step of etching one of the three layers of the same substrate under the adjusted flow rate based on the measured width of the etched pattern, wherein the measuring step and the adjusting step are performed during the etching process.

17. The method as recited in claim 13, further comprising a step of etching the silicon-contained anti-reflective coating layer under the adjusted flow rate based on the measured width of the mask pattern.

18. The method as recited in claim 13, wherein the adjusting step comprises increasing a flow rate ratio of CF₄ to CHF₃ when the measured width is greater than a desired width and decreasing the flow rate ratio of CF₄ to CHF₃ when the measured width is smaller than the desired width.

19. The method as recited in claim 13, wherein the adjusting step comprises increasing a RF bias power applied to the substrate when the measured width is smaller than a desired width and decreasing the RF bias power when the measured width is greater than the desired width.
